(19) United States
(12) Patent Application Publication
(10) Pub. No.: US 2008/0303573 A1
(43) Pub. Date: Dec. 11, 2008

(54) DATA-RETENTION LATCH FOR SLEEP MODE APPLICATION

(75) Inventors: Shang-Chih Hsieh, Hsinchu (TW); Jeng-Huang Wu, Hsinchu (TW)

Correspondence Address: WPAT, PC, 7225 BEVERLY ST., ANNANDALE, VA, 22003, US

(73) Assignee: FARADAY TECHNOLOGY CORPORATION, Hsinchu (TW)

(21) Appl. No.: 11/760,871

(22) Filed: Jun. 11, 2007

(51) Int. Cl. H03K 3/00; H03K 3/289

(52) U.S. Cl. 327/199; 327/202

(57) ABSTRACT

A latch includes a data input terminal for receiving a data signal; a data output terminal for outputting the data signal; a first control terminal for receiving a control signal to set or reset the data signal derived from the data output terminal; a sleep signal input terminal for receiving a sleep signal to determine a sleep mode; a first logic circuit having input terminals coupled to the data input terminal, the first control terminal and the sleep signal input terminal and an output terminal coupled to the data output terminal; and a second logic circuit having input terminals coupled to the data output terminal, the first control terminal and the sleep signal input terminal and an output terminal coupled to the data input terminal; wherein the first logic circuit or the second logic circuit ignores the first control signal in response to the sleep signal when the latch is operated in the sleep mode.

### FIELD OF THE INVENTION

The present invention relates to a latch, and more particularly to a data-retention latch for a sleep mode application.

### BACKGROUND OF THE INVENTION

In recent years, many semiconductor integrated logic devices have been designed to operate in an active mode and a sleep mode. The active mode is the state where the normal operation of the logic device is performed due to all the elements in the logic device are powered. The sleep mode is the state where some elements in the logic device are un-powered because of its purpose of reducing the power consumption, but some elements in the logic devices are still powered because of its purpose of without losing the data or the setting values stored in the logic device. Because the data or the setting values are still stored in the logic device when the logic device is operated in the sleep mode, the logic device can work normally according to the stored data and setting values after the logic device returns from the sleep mode to the active mode. For storing these data or setting values when the logic device is operated in the sleep mode, a latch applied in the sleep mode is developed. Moreover, the sleep mode may be termed the power down mode.

FIG. 1 is a schematic diagram showing the conventional logic device capable of being operated in both the active and sleep mode. The logic device includes a switch SW, a main circuit 11, an isolation interface 15, and a latch 13. According to a sleep signal SL, the switch serves to connect the main circuit 11 to a power supply of Vcc in the active mode, or disconnect the main circuit 11 to the power supply of Vcc in the sleep mode. When the sleep signal SL is in the logic high level (i.e., SL=1), the logic device enters the sleep mode; when the sleep signal SL is in the logic low level (i.e., SL=0), the logic device enters the active mode.

When the logic device is operated in the active mode, the signals transmitted between the main circuit 11 and the latch 13 are not affected by the isolation interface 15, In another word, the signals coming from the main circuit 11 are directly passed to the latch 13 by the isolation interface 15 without any changing; and the signals coming from the latch 13 are also directly passed to the main circuit 11 by the isolation interface 15 without any changing.

When the logic device is operated in the sleep mode, the main circuit 11 is disconnected to the power supply of Vcc. To guarantee the latch 13 can work normally, so as to prevent the data stored in the latch 13 from being lost, the isolation interface 15 must isolate the signals coming from the main circuit 11 to the latch 13, and provides other signals to the latch 13.

An example of this sort is explained below. FIG. 2 is a diagram showing a conventional latch. Generally, the latch 13 includes a data input terminal D, a clock input terminal CK, a set terminal SB, a reset terminal RB, and a data output terminal Q. The data input terminal D serves to temporarily store the data in the latch 13 according to a clock signal applied to the clock input terminal CK; the data output terminal Q serves to output the data temporarily stored in the latch 13; and the set terminal SB and the reset terminal RB together serve as a control terminal for directly changing the state of the signal derived from the data output terminal Q. For example, the signal derived from the data output terminal Q will stay at the prior state when the reset terminal RB is in the logic high level (i.e., RB=1), and the signal derived from the data output terminal Q will directly change to the logic low level (i.e., signal=0) when the reset terminal RB is in the logic low level (i.e., RB=0); the signal derived from the data output terminal Q will stay at the prior state when the set terminal SB is in the logic high level (i.e., SB=1), and the signal derived from the data output terminal Q will directly change to the logic high level (i.e., signal=1) when the set terminal SB is in the logic low level (i.e., SB=0). In another word, for making the latch 13 capable of controlled by the clock signal, the set terminal SB and the reset terminal RB must be both in the logic high level (i.e., SB=1, RB=1).

When the logic device is operated in the active mode, the main circuit 11 can directly access data stored in the latch 13. In another word, the main circuit 11 can control the data input terminal D, the clock input terminal CK, the set terminal SB, and the reset terminal RB of the latch 13 through the isolation interface 15.

However, when the logic device is operated in the sleep mode, the signals derived from the main circuit 11 will drop to the logic low level (i.e., signal=0) due to the main circuit 11 is disconnected to the power supply of Vcc. Therefore, the isolation interface 15 must isolate the dropped signals derived from the main circuit 11 to the set terminal SB and the reset terminal RB of the latch 13, so as to prevent the output signal derived from the output terminal Q from being affected. In another word, the isolation interface 15 must provide signals in the logic high level (i.e., signal=1) to the set terminal SB and the reset terminal RB by itself to make the latch 13 can work normally in the sleep mode.

FIG. 3 is a schematic diagram showing a conventional latching circuit disclosed in U.S. Pat. No. 6,310,491. The latching circuit SLC1 includes a latch FF1, a first switch SW1, and a second switch SW2. The latch FF1 further includes a data input terminal D, a clock input terminal φ, a sleep signal input terminal SL, an inverted sleep signal input terminal SLB, a set terminal SB, a reset terminal RB, a data output terminal Q, and an inverted data output terminal QB. The data input terminal D serves to temporarily store the data in the latch FF1 according to the clock signal applying to the clock input terminal φ; the data output terminal Q and the inverted data output terminal QB serve to output the data temporarily stored in the latch 13, wherein the data derived from the data output terminal Q is inverted to the data derived from the inverted data output terminal QB; the set terminal SB and the reset terminal RB together serve as a control terminal for directly changing the state of the signal derived from the data output terminal Q and the inverted data output terminal QB. For example, the signal derived from the data output terminal Q will stay at the prior state when the reset terminal RB is in the logic low level (i.e., RB=0), and a signal in the logic low level (i.e., signal=0) will be directly derived from the data output terminal Q when the reset terminal RB is in the logic high level (i.e., RB=1); the signal derived from the data output terminal Q will stay at the prior state when the set terminal SB is in the logic high level (i.e., SB=1), and a signal in the logic high level (i.e., signal=1) will be directly derived from the data output terminal Q when the set terminal SB is in the logic low level (i.e., SB=0).

Moreover, the first switch SW1 and the second switch SW2 together serve as an isolation interface. Through the first switch SW1 and the second switch SW2, which are controlled by a data keep signal KP, the data stored in the FF1 can be prevented from being lost during the switch between the sleep mode and the active mode. In another word, the data keep signal KP can control the first switch SW1 and the second switch SW2 to connect the reset terminal RB to the ground and connect the set terminal SB to the power supply of VDD in the sleep mode, so as to guarantee the latch FF1 can work normally in the sleep mode.

However, the isolation interface not only makes the latch FF1 can work normally in the sleep mode, but also increases the layout area and the cost of the latching circuit SLC1. Therefore, designing a latch capable of operated in the sleep mode, having a relatively small layout area, and without an isolation interface, is the main purpose of the present invention.

### SUMMARY OF THE INVENTION

Therefore, the present invention relates to a latch capable of operated in the sleep mode having a relatively small layout area.

The present invention discloses a latch, comprising: a data input terminal for receiving a data signal; a data output terminal for outputting the data signal; a first control terminal for receiving a control signal to set or reset the data signal derived from the data output terminal; a sleep signal input terminal for receiving a sleep signal to determine a sleep mode; a first logic circuit having input terminals coupled to the data input terminal, the first control terminal and the sleep signal input terminal and an output terminal coupled to the data output terminal; and, a second logic circuit having input terminals coupled to the data output terminal, the first control terminal and the sleep signal input terminal and an output terminal coupled to the data input terminal; wherein the first logic circuit or the second logic circuit ignores the first control signal in response to the sleep signal when the latch is operated in the sleep mode.

Moreover, the present invention discloses a master-slave flip-flop, comprising: a data input terminal for receiving a data signal; a data output terminal for outputting the data signal; a first control terminal for receiving a control signal to set or reset the data signal derived from the data output terminal; a sleep signal input terminal for receiving a sleep signal to determine a sleep mode; a master latch having input terminals coupled to the first control terminal, the data input terminal, and the sleep signal input terminal and an output terminal; and, a slave latch having input terminals coupled to the first control terminal, the output terminal of the master latch, and the sleep signal input terminal for temporarily storing the data signal and an output terminal coupled to the data output terminal; wherein the master latch or the slave latch ignores the first control signal in response to the sleep signal when the master-slave flip-flop is operated in the sleep mode.

### BRIEF DESCRIPTION OF THE DRAWINGS

The above contents of the present invention will become more readily apparent to those ordinarily skilled in the art after reviewing the following detailed description and accompanying drawings, in which:

FIG. 1 is a schematic diagram showing the conventional logic device capable of being operated in both the active and sleep mode.

FIG. 2 is a diagram showing a conventional latch.

FIG. 3 is a schematic diagram showing a conventional latching circuit disclosed in U.S. Pat. No. 6,310,491.

FIG. 4A is a schematic diagram showing the latch of the first embodiment of present invention.

FIG. 4B is a timing diagram showing signals operated in the sleep mode according to the first embodiment.

FIG. 5 is a schematic diagram showing a master-slave flip-flop of the present invention.

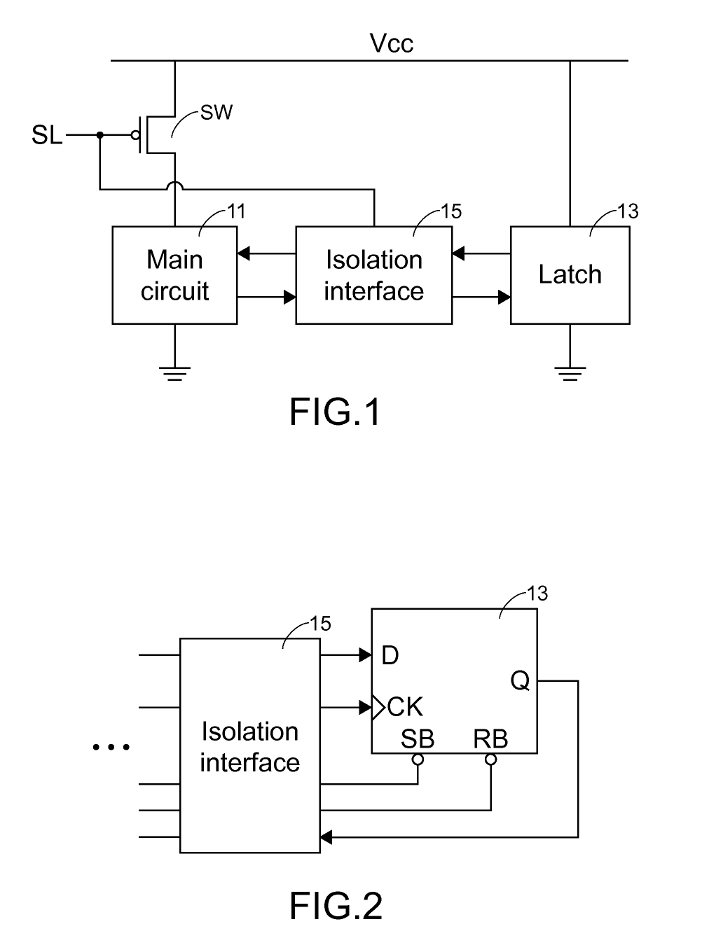

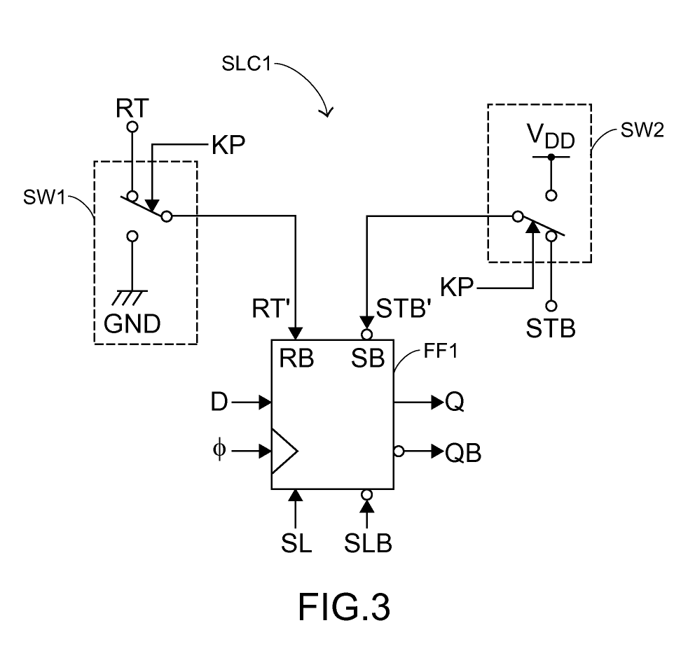

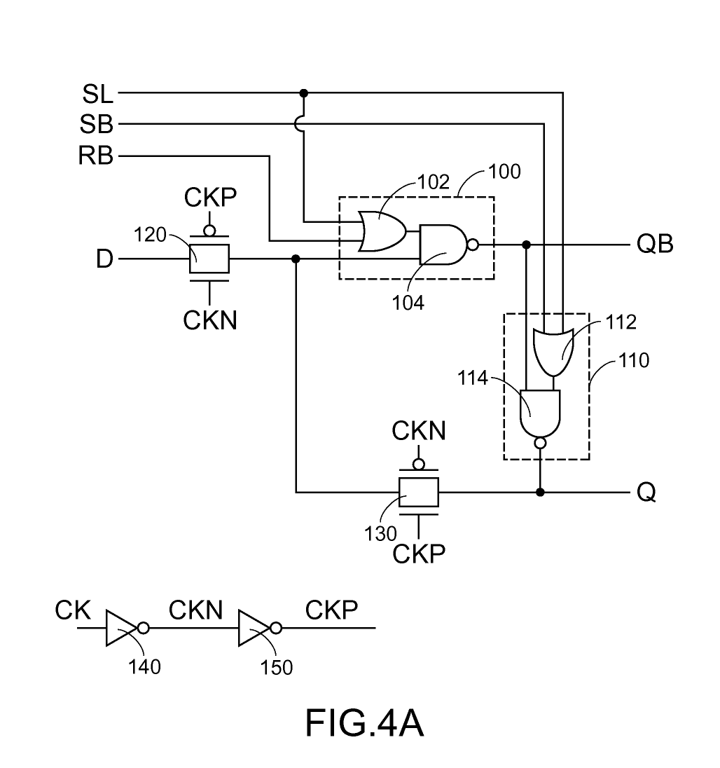

### DETAILED DESCRIPTION OF THE PREFERRED EMBODIMENT

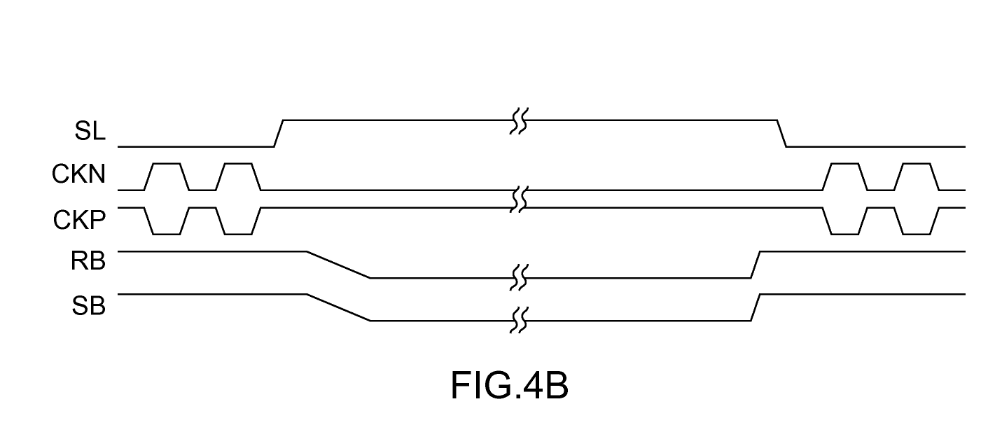

FIG. 4A is a schematic diagram showing the latch of the first embodiment of present invention. FIG. 4B is a timing diagram showing signals operated in the sleep mode according to the first embodiment. In the first embodiment, the latch is operated in the sleep mode when the sleep signal input terminal SL is in the logic high level (i.e., SL=1), and the latch is operated in the active mode when the sleep signal input terminal SL is in the logic low level (i.e., SL=0). Moreover, the data input terminal D serves to temporarily store the data in the latch according to a clock signal applying to the clock input terminal CK; and the data output terminal Q and the inverted data output terminal QB serve to output the data temporarily stored in the latch, wherein the data derived from the data output terminal Q is inverted to the data derived from the inverted data output terminal QB. Moreover, the data output terminal Q will stay at the prior state when the reset terminal RB is in the logic high level (i.e., RB=1), and a signal in the logic low level (i.e., signal=0) will be directly derived from the data output terminal Q when the reset terminal RB is in the logic low level (i.e., RB=0); the data output terminal Q will stay at the prior state when the set terminal SB is in the logic high level (i.e., RB=1), and a signal in the logic high level (i.e., signal=1) will be directly derived from the data output terminal Q when the set terminal SB is in the logic low level (i.e., RB=0). In another word, for making the latch capable of controlled by the clock signal, the set terminal SB and the reset terminal RB must be both in the logic high level (i.e., SB=1, RB=1).

As depicted in FIG. 4A, the latch of the first embodiment includes a first logic circuit 100, a second logic circuit 110, a first transmission gate 120, a second transmission gate 130, a first NOT gate 140, and a second NOT gate 150. The first logic circuit 100 further includes a first OR gate 102 and a first NAND gate 104; the second logic circuit 110 further includes a second OR gate 112 and a second NAND gate 114. The first NOT gate 140 and the second NOT gate 150, coupled in series and connected to the clock input terminal CK, serve to generate clock signals CKN and CKP, wherein the clock signal CKN is inverted to the clock signal CKP. Both the first transmission gate 120 and the second transmission gate 130 are controlled by the clock signals CKN and CKP, but the first transmission gate 120 and the second transmission gate 130 are operated in different time periods.

One terminal of the first transmission gate 120 is coupled to the data input terminal D, and the other terminal of the first transmission gate 120 is coupled to a first input terminal of the first NAND gate 104; the two input terminals of the first OR gate 102 are coupled to the sleep signal input terminal SL and the reset terminal RB, respectively, and the output terminal of the first OR gate 102 is coupled to a second input terminal of the first NAND gate 104; and the output terminal of the first NAND gate 104 is the inverted data output terminal QB. Moreover, the inverted data output terminal QB is coupled to a first input terminal of the second NAND 114; the sleep signal input terminal SL and the set terminal SB are coupled to the two input terminals of the second OR gate 112, respectively, and the output terminal of the second OR gate 112 is coupled to the second input terminal of the second NAND gate 114; and the output terminal of the second NAND 114 is the data output terminal Q. Moreover, one terminal of the second transmission gate 130 is coupled to the data output terminal Q, and the other terminal of the second transmission gate 130 is coupled to the first input terminal of the first NAND 104.

When the latch depicted in FIG. 4A is operated in the active mode, the sleep signal input terminal SL is in the logic low level (SL=0), the reset terminal RB and the set terminal SB are in the logic high level (i.e., RB=1, SB=1). Assuming the data input terminal D is in the logic high level (i.e., D=1), the inverted data output terminal QB will be in the logic low level (i.e., QB=0) and the data output terminal Q will be in the logic high level (i.e., Q=1) if the first transmission gate 120 is operating but the second transmission gate 130 is not operating according to the clock signals CKN and CKP. When the first transmission gate 120 is not operating but the second transmission gate 130 is operating according to the clock signals CKN and CKP, the data, in the logic high level (i.e., data=1) and derived from the data input terminal D, is latched in the latch. Moreover, assuming the data input terminal D is in the logic low level (i.e., D=0), the inverted data output terminal QB will be in the logic high level (i.e., QB=1) and the data output terminal Q will be in the logic low level (i.e., Q=0) if the first transmission gate 120 is operating but the second transmission gate 130 is not operating. When the first transmission gate 120 is not operating but the second transmission gate 130 is operating, the data, in the logic low level (i.e., data=0) and derived from the data input terminal D, is latched in the latch.

When the latch is operated in the active mode and the set terminal SB is asserted, the sleep signal input terminal SL and the set terminal SB are in the logic low level (i.e., SL=0, SB=0), and the reset terminal RB is in the logic high level (i.e., RB=1). At this stage, the data output terminal Q is in the logic high level (Q=1) and the inverted data output terminal QB is in the logic low level (QB=0).

When the latch is operated in the active mode and the reset terminal RB is asserted, the sleep signal input terminal SL and the reset terminal RB are in the logic low level (i.e., SL=0, RB=0), and the set terminal SB is in the logic high level (i.e., SB=1). At this stage, the data output terminal Q is in the logic low level (Q=0) and the inverted data output terminal QB is in the logic high level (QB=1).

When the sleep signal input terminal SL is in the logic high level (i.e., SL=1), the latch is operated in the sleep mode. At this stage, the data output terminal Q and the inverted data output terminal QB will stay at the prior state and without being changed no matter what the state of the set terminal SB and the reset terminal RB is. In another word, the latch can ignore the state of the set terminal SB and the state of the reset terminal RB if the latch is operated in the sleep mode. Therefore, the data already stored in the latch when the latch is operated in the sleep mode can be outputted without any changing when the latch returns from the sleep mode to the active mode.

As depicted in FIG. 4B, when the latch enters the sleep mode, the reset terminal RB and the set terminal SB gradually decrease from the logic high level (i.e., RB=1, SB=1) to the logic low level (i.e., RB=0, SB=1). Because the latch of the present invention can ignore the state of the reset terminal RB and the set terminal SB at this stage, the latch of the present invention still can maintain data without any changing.

Moreover, the asserted logic level of the sleep signal input terminal SL, the reset terminal RB, and the set terminal SB can be adjusted according to any specific purpose. The circuits of the first logic circuit 100 and the second logic circuit 110 can be also adjusted according to the different setting of each terminal of the latch. The latch can only comprise either one of the reset terminal RB or the set terminal SB is necessary.

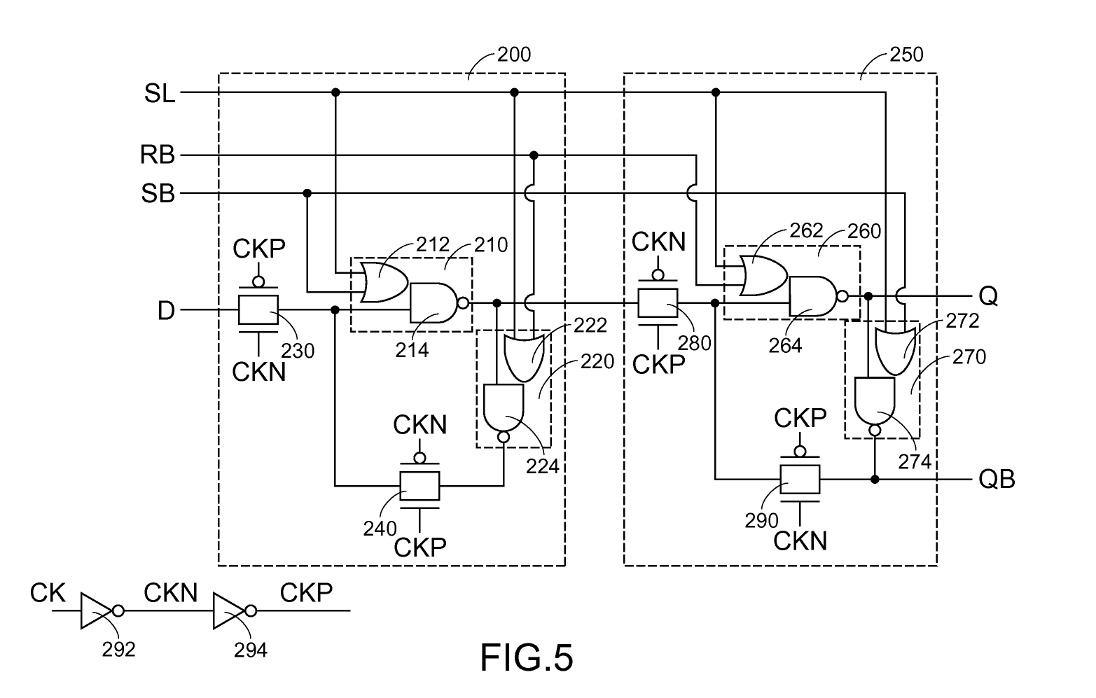

FIG. 5 is a schematic diagram showing a master-slave flip-flop of the present invention. The master-slave flip-flop includes a master latch 200 and a slave latch 250, and both the master latch 200 and the slave latch 250 have the same circuit configuration as the latch depicted in FIG. 4A. The master latch 200 includes a third logic circuit 210, a fourth logic circuit 220, a third transmission gate 230, and a fourth transmission gate 240. The third logic circuit 210 further includes a third OR gate 212 and a third NAND gate 214. The fourth logic circuit 220 further includes a fourth OR gate 222 and a fourth NAND gate 224. The slave latch 250 includes a fifth logic circuit 260, a sixth logic circuit 270, a fifth transmission gate 280, and a sixth transmission gate 290. The fifth logic circuit 260 further includes a fifth OR gate 262 and a fifth NAND gate 264. The sixth logic circuit 270 further includes a sixth OR gate 272 and a sixth NAND gate 274. The third NOT gate 292 and the fourth NOT gate 294, coupled in series and connected to the clock input terminal CK, serve to generate clock signals CKN and CKP, wherein the clock signal CKN is inverted to the clock signal CKP. The third transmission gate 230, the fourth transmission gate 240, the fifth transmission gate 280, and the sixth transmission gate 290 are all controlled by the clock signals CKN and CKP, wherein the third transmission gate 230 and the fourth transmission gate 240 are operated in different time periods; the third transmission gate 230 and the sixth transmission gate 290 are operated in the same time periods; and the fourth transmission gate 240 and the fifth transmission gate 280 are operated in the same time periods.

Moreover, the data input terminal D of the master-slave flip-flop is the data input terminal of the master latch 200, and coupled to the one terminal of the third transmission gate 230, and the other terminal of the third transmission gate 230 is coupled to the first input terminal of the third NAND gate 214; the sleep signal input terminal SL and the set terminal SB are coupled to the two input terminals of the third OR gate 212; the output terminal of the third OR gate 212 is coupled to the second input terminal of the third NAND gate 214; the output terminal of the third NAND gate 214 is coupled to the data input terminal of the slave latch 250 and the first input terminal of the fourth NAND gate 224; the sleep signal input terminal SL and the reset terminal RB are coupled together and to be connected to the input terminal of the fourth OR gate 222, the output terminal of the fourth OR gate 222 is coupled to the second input terminal of the fourth NAND gate 224; one terminal of the fourth transmission gate 240 is coupled to the output terminal of the fourth NAND gate 224, and the other terminal of the fourth transmission gate 240 is coupled to the first input terminal of the third NAND gate 214.

The data input terminal of the slave latch 250 is coupled to the one terminal of the fifth transmission gate 280, and the other terminal of the fifth transmission gate 280 is coupled to the first input terminal of the fifth NAND gate 264; the sleep signal input terminal SL and the reset terminal RB are coupled to the two input terminals of the fifth OR gate 262; the output terminal of the fifth OR gate 262 is coupled to the second input terminal of the fifth NAND gate 264, and the output terminal of the fifth NAND gate 264 is the data output terminal Q of the master-slave flip-flop. Moreover, the data output terminal Q of the master-slave flip-flop is coupled to the first input terminal of the sixth NAND gate 274; the sleep signal input terminal SL and the set terminal SB are coupled together and to be connected to the input terminal of the sixth OR gate 272, the output terminal of the sixth OR gate 272 is coupled to the second input terminal of the sixth NAND gate 274; the output terminal of the sixth NAND gate 274 is the inverted data output terminal QB of the master-slave flip-flop. Moreover, one terminal of the sixth transmission gate 290 is coupled to the inverted data output terminal QB of the master-slave flip-flop, and the other terminal of the sixth transmission gate 290 is coupled to the first input terminal of the fifth NAND gate 264.

When the master-slave flip-flop is operated in the active mode, the data derived from the data input terminal D is sequentially stored in the master latch 200 and the slave latch 250 in response to the clock signals CKN and CKP. Furthermore, when the master-slave flip-flop is operated in the active mode, the data output terminal Q of the master-slave flip-flop can be controlled by the set terminal SB and the reset terminal RB.

When the master-slave flip-flop is operated in the sleep mode, the master-slave flip-flop can ignore the state of the reset terminal RB and the set terminal SB. Therefore, the data already stored in the master latch 200 and the slave latch 250 can be outputted without any changing when the latch returns from the sleep mode to the active mode.

Moreover, because both the master latch 200 and the slave latch 250 can serve to store data when the master-slave flip-flop is operated in the sleep mode, therefore, only one of the master latch 200 and the slave latch 250 is necessary to be connected to the power supply if the low power-consumption is concerned. The data already stored in the master-slave flip-flop can also be outputted without any changing when the master-slave flip-flop returns from the sleep mode to the active mode.

Therefore, the relatively large layout area and the relatively higher cost resulted in the prior-art latch having an additional isolation interface can be avoided in the latch of the present invention. Moreover, the logic circuits 100, 110, 210, 220, 260 and 270 of the present invention can be implemented by an AOI structure (And-Or-Inverter). In another word, the 3-terminal logic circuits 100, 110, 210, 220, 260 and 270 can be implemented by only six transistors, therefore, the circuit configuration of the present invention can be simpler, and the layout area of the present invention can be also smaller.

While the invention has been described in terms of what is presently considered to be the most practical and preferred embodiments, it is to be understood that the invention needs not be limited to the disclosed embodiment. On the contrary, it is intended to cover various modifications and similar arrangements included within the spirit and scope of the appended claims, which are to be accorded with the broadest interpretation so as to encompass all such modifications and similar structures.

What is claimed is:

1. A latch, comprising:
a data input terminal for receiving a data signal;
a data output terminal for outputting the data signal;
a first control terminal for receiving a control signal to set or reset the data signal derived from the data output terminal;
a sleep signal input terminal for receiving a sleep signal to determine a sleep mode;
a first logic circuit having input terminals coupled to the data input terminal, the first control terminal and the sleep signal input terminal and an output terminal coupled to the data output terminal; and
a second logic circuit having input terminals coupled to the data output terminal, the first control terminal and the sleep signal input terminal and an output terminal coupled to the data input terminal;
wherein the first logic circuit or the second logic circuit ignores the first control signal in response to the sleep signal when the latch is operated in the sleep mode.

2. The latch according to claim 1, wherein the latch further comprises a second control terminal and the first control terminal is a set terminal and the second control terminal is a reset terminal.

3. The latch according to claim 2, wherein the first logic circuit further comprises:
a first OR gate having input terminals coupled to the sleep signal input terminal and the reset terminal; and
a first NAND gate having input terminals coupled to the data input terminal and an output terminal of the first OR gate and an output terminal coupled to the data output terminal.

4. The latch according to claim 2, wherein the second logic circuit further comprises:
a second OR gate having input terminals coupled to the sleep signal input terminal and the set terminal; and
a second NAND gate having input terminals coupled to the data output terminal and an output terminal of the second OR gate and an output terminal coupled to the data input terminal.

5. A master-slave flip-flop, comprising:
a data input terminal for receiving a data signal;
a data output terminal for outputting the data signal;
a first control terminal for receiving a control signal to set or reset the data signal derived from the data output terminal;
a sleep signal input terminal for receiving a sleep signal to determine a sleep mode;
a master latch having input terminals coupled to the first control terminal, the data input terminal, and the sleep signal input terminal and an output terminal; and
a slave latch having input terminals coupled to the first control terminal, the output terminal of the master latch, and the sleep signal input terminal for temporarily storing the data signal and an output terminal coupled to the data output terminal;
wherein the master latch or the slave latch ignores the first control signal in response to the sleep signal when the master-slave flip-flop is operated in the sleep mode.

6. The master-slave flip-flop according to claim 5, wherein the master latch further comprises:
a first logic circuit having input terminals coupled to the data input terminal, the first control terminal and the sleep signal input terminal and an output terminal; and
a second logic circuit having input terminals coupled to the output terminal of the first logic circuit, the first control terminal and the sleep signal input terminal and an output terminal coupled to the data input terminal;
wherein the first logic circuit or the second logic circuit ignores the first control signal in response to the sleep signal when the latch is operated in the sleep mode.

7. The master-slave flip-flop according to claim 6, wherein the slave latch further comprises:
a third logic circuit having input terminals coupled to the output terminal of the first logic circuit, the first control terminal and the sleep signal input terminal and an output terminal coupled to the data output terminal; and
a fourth logic circuit having input terminals coupled to the data output terminal, the first control terminal and the sleep signal input terminal and an output terminal coupled to the output terminal of the first logic circuit;
wherein the third logic circuit or the fourth logic circuit ignores the first control signal in response to the sleep signal when the latch is operated in the sleep mode.

8. The latch according to claim 5, wherein the latch further comprises a second control terminal and the first control terminal is a set terminal and the second control terminal is a reset terminal.
